(19) United States
(12) Patent Application Publication
(10) Pub. No.: US 2016/0099268 A1
(43) Pub. Date: Apr. 7, 2016

(54) IMAGING APPARATUS AND IMAGING SYSTEM

(71) Applicant: CANON KABUSHIKI KAISHA, Tokyo (JP)

(72) Inventor: Masaaki Minowa, Kawasaki-shi (JP)

(21) Appl. No.: 14/855,616

(22) Filed: Sep. 16, 2015

(30) Foreign Application Priority Data
Oct. 7, 2014 (JP) 2014-206281

(51) Int. Cl. H01L 27/146; H04N 5/378; H04N 5/369

(52) U.S. Cl. CPC H01L 27/14609; H04N 5/3696; H01L 27/14625; H04N 5/378

(57) ABSTRACT

Provided is an imaging apparatus, including a pixel region in which a plurality of pixels are arranged, the plurality of pixels each including: a plurality of photoelectric converters configured to generate charges corresponding to an amount of incident light; a plurality of charge holding portions arranged correspondingly to the plurality of photoelectric converters and configured to hold charges generated by the plurality of photoelectric converters respectively; and a light condensing portion arranged so as to be shared by the plurality of photoelectric converters and configured to guide the incident light to the plurality of photoelectric converters. In the imaging apparatus, a height (Vb) of a first potential barrier between two charge holding portions included in the a pixel is lower than a height (Va) of a second potential barrier between two charge holding portions included in different pixels.

### BACKGROUND OF THE INVENTION

1. Field of the Invention

The present invention relates to an imaging apparatus and an imaging system.

2. Description of the Related Art

In Japanese Patent Application Laid-Open Nos. 2007-243744 and 2013-172210, there are proposed imaging apparatus each having both a global electronic shutter function and a focus detection function by using a phase difference method on an imaging plane. Those imaging apparatus include a plurality of photoelectric converters configured to output signal charges used for image signals and signal charges used for focus detection, and a plurality of charge holding portions configured to hold the signal charges transferred from the photoelectric converters.

In the imaging apparatus disclosed in Japanese Patent Application Laid-Open Nos. 2007-243744 and 2013-172210, when at least one of the plurality of charge holding portions is saturated, the charges originally required to be held by the saturated charge holding portion may leak to the charge holding portion in an adjacent pixel. Further, the charges originally required to be held by the saturated charge holding portion may not be transferred from the photoelectric converter but remain in the photoelectric converter. For those reasons, when at least one of the plurality of charge holding portions is saturated, image quality may deteriorate even if the other charge holding portions are not saturated.

### SUMMARY OF THE INVENTION

The present invention has been made in view of the above-mentioned problem, and has an object to improve image quality in an imaging apparatus having both a global electronic shutter function and a focus detection function by using a phase difference method on an imaging plane.

According to one embodiment of the present invention, there is provided an imaging apparatus, including a pixel region in which a plurality of pixels are arranged, the plurality of pixels each including: a plurality of photoelectric converters configured to generate charges corresponding to an amount of incident light; a plurality of charge holding portions arranged correspondingly to the plurality of photoelectric converters and configured to hold charges generated by the plurality of photoelectric converters respectively; and a light condensing portion arranged so as to be shared by the plurality of photoelectric converters and configured to guide the incident light to the plurality of photoelectric converters, in which a height Vb of a first potential barrier between two of the plurality of charge holding portions included in a same pixel is lower than a height Va of a second potential barrier between two of the plurality of charge holding portions included in different pixels.

According to another embodiment of the present invention, there is provided an imaging apparatus, including: a pixel region in which a plurality of pixels are arranged, the plurality of pixels each including: a plurality of photoelectric converters configured to generate charges corresponding to an amount of incident light; a plurality of charge holding portions arranged correspondingly to the plurality of photoelectric converters and configured to hold charges generated by the plurality of photoelectric converters respectively; and a light condensing portion arranged so as to be shared by the plurality of photoelectric converters and configured to guide the incident light to the plurality of photoelectric converters; a first isolation portion formed between adjacent ones of the plurality of charge holding portions included in a same pixel, the first isolation portion being formed of a semiconductor region having a conductivity type that is different from a conductivity type of a semiconductor region forming the plurality of charge holding portions; and a second isolation portion formed between adjacent ones of the plurality of charge holding portions included in different pixels, the second isolation portion being formed of an insulating material.

According to another embodiment of the present invention, there is provided an imaging apparatus, including: a pixel region in which a plurality of pixels are arranged, the plurality of pixels each including: a plurality of photoelectric converters configured to generate charges corresponding to an amount of incident light; a plurality of charge holding portions arranged correspondingly to the plurality of photoelectric converters and configured to hold charges generated by the plurality of photoelectric converters respectively; and a light condensing portion arranged so as to be shared by the plurality of photoelectric converters and configured to guide the incident light to the plurality of photoelectric converters; a first isolation portion formed between adjacent ones of the plurality of charge holding portions included in a same pixel, the first isolation portion being formed of a first semiconductor region having a conductivity type that is different from a conductivity type of a semiconductor region forming the plurality of charge holding portions; and a second isolation portion formed between adjacent ones of the plurality of charge holding portions included in different pixels, the second isolation portion being formed of a second semiconductor region having the conductivity type that is different from the conductivity type of the semiconductor region forming the plurality of charge holding portions, and in which an impurity concentration of the first semiconductor region is lower than an impurity concentration of the second semiconductor region.

According to another embodiment of the present invention, there is provided an imaging apparatus, including a pixel region in which a plurality of pixels are arranged, the plurality of pixels each including: a plurality of photoelectric converters configured to generate charges corresponding to an amount of incident light; a plurality of charge holding portions arranged correspondingly to the plurality of photoelectric converters and configured to hold charges generated by the plurality of photoelectric converters respectively; and a light condensing portion arranged so as to be shared by the plurality of photoelectric converters and configured to guide the incident light to the plurality of photoelectric converters, in which a height Vb of a first potential barrier between two of the plurality of charge holding portions included in a same pixel is lower than a difference ΔVdep between a depletion voltage of one of the plurality of photoelectric converters and a depletion voltage of corresponding one of the plurality of charge holding portions.

Further features of the present invention will become apparent from the following description of exemplary embodiments with reference to the attached drawings.

### BRIEF DESCRIPTION OF THE DRAWINGS

FIG. 1 is a diagram for illustrating a configuration of an imaging apparatus according to a first embodiment of the present invention.

FIG. 2 is a circuit diagram of a pixel according to the first embodiment.

FIG. 3A and FIG. 3B are drive timing charts of the imaging apparatus according to the first embodiment.

FIG. 4 is a top view of the pixel according to the first embodiment.

FIG. 5 is a potential diagram of the pixel according to the first embodiment.

FIG. 6A and FIG. 6B are potential diagrams for illustrating effects of the first embodiment.

FIG. 7A, FIG. 7B, and FIG. 7C are illustrations of cross-sectional structures of the pixel according to the first embodiment.

FIG. 8A and FIG. 8B are illustrations of cross-sectional structures of the pixel according to the first embodiment.

FIG. 9 is a potential diagram of a pixel according to a second embodiment of the present invention.

FIG. 10A is a graph for illustrating effects of the second embodiment, and FIG. 10B, FIG. 10C, and FIG. 10D are potential diagrams for illustrating the effects of the second embodiment.

FIG. 11 is a drive timing chart of an imaging apparatus according to a third embodiment of the present invention.

FIG. 12 is a drive timing chart of an imaging apparatus according to a fourth embodiment of the present invention.

FIG. 13 is a circuit diagram of a pixel according to a fifth embodiment of the present invention.

FIG. 14 is a drive timing chart of an imaging apparatus according to the fifth embodiment.

FIG. 15 is a top view of the pixel according to the fifth embodiment.

FIG. 16 is a circuit diagram of a pixel according to a sixth embodiment of the present invention.

FIG. 17 is a drive timing chart of an imaging apparatus according to the sixth embodiment.

FIG. 18 is a top view of the pixel according to the sixth embodiment.

FIG. 19 is a potential diagram of the pixel according to the sixth embodiment.

FIG. 20 is a block diagram of an imaging system according to a seventh embodiment of the present invention.

### DESCRIPTION OF THE EMBODIMENTS

Preferred embodiments of the present invention will now be described in detail in accordance with the accompanying drawings. In the drawings of each of the embodiments, components having the same functions are denoted by the same reference symbols, and overlapping descriptions thereof are sometimes omitted.

### First Embodiment

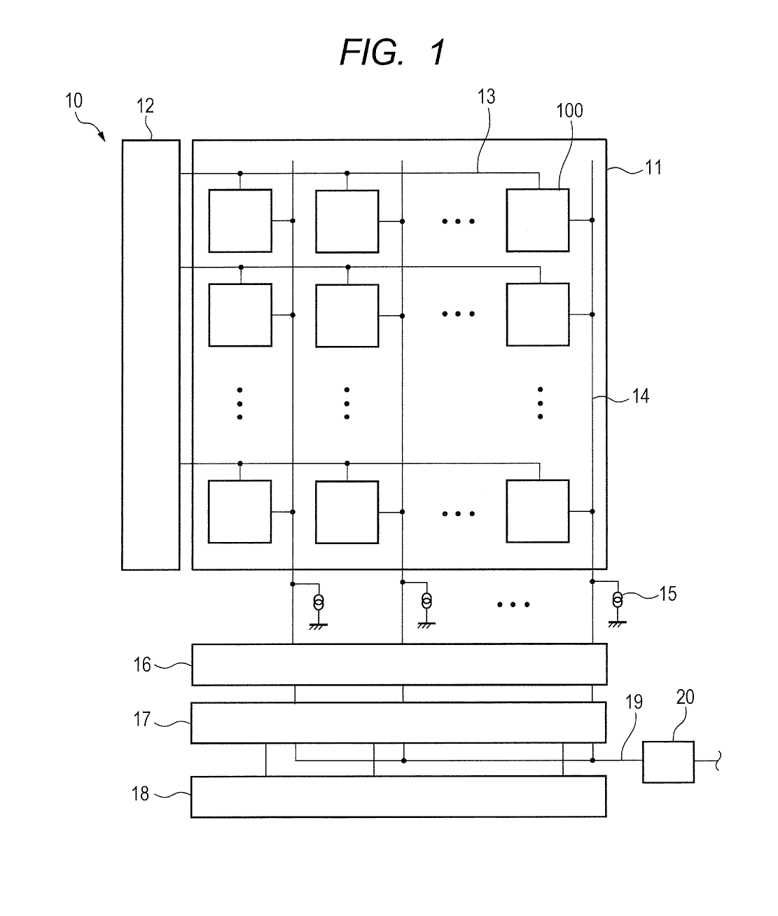

FIG. 1 is a diagram for illustrating a configuration of an imaging apparatus according to a first embodiment of the present invention. An imaging apparatus 10 includes a pixel region 11, a vertical scanning circuit 12, a column amplifier portion 16, a column signal holding portion 17, a horizontal scanning circuit 18, and an output circuit 20. The pixel region 11 is a light receiving portion of the imaging apparatus 10, and includes a plurality of pixels 100 arranged in rows and columns. The vertical scanning circuit 12 is a circuit configured to transmit control signals to the pixels 100. The vertical scanning circuit 12 is connected to the pixels 100 via control signal lines 13 arranged for respective rows of the imaging apparatus 10. Note that, in FIG. 1, the control signal lines 13 are illustrated as lines each connected to each pixel, but the control signal lines 13 may each be formed of a plurality of wirings so that a plurality of kinds of control signals may be transmitted.

The pixel 100 is an element configured to convert incident light into an electrical signal and output the converted electrical signal. The respective pixels 100 are connected to vertical signal lines 14 arranged for respective columns of the imaging apparatus 10. A signal from the pixel 100 is output to the column amplifier portion 16 by a current supplied from a current source 15 connected to each vertical signal line 14. The column amplifier portion 16 includes an amplifier circuit and the like. The column amplifier portion 16 performs processing such amplification on the input signal, and outputs the resultant signal to the column signal holding portion 17. The column signal holding portion 17 is a circuit configured to temporarily hold the signal input from the column amplifier portion 16. The horizontal scanning circuit 18 transmits a control signal for column select and the like to the column signal holding portion 17. Based on the control signal from the horizontal scanning circuit 18, the column signal holding portion 17 sequentially outputs the signals from the respective pixel columns to the output circuit 20 via an output signal line 19. The output circuit 20 performs processing such as amplification on the input signal, and outputs the resultant signal to a signal processing unit or the like connected at the subsequent stage of the imaging apparatus 10. The above-mentioned configuration of the imaging apparatus 10 is merely an example, and another circuit or the like may be added as appropriate.

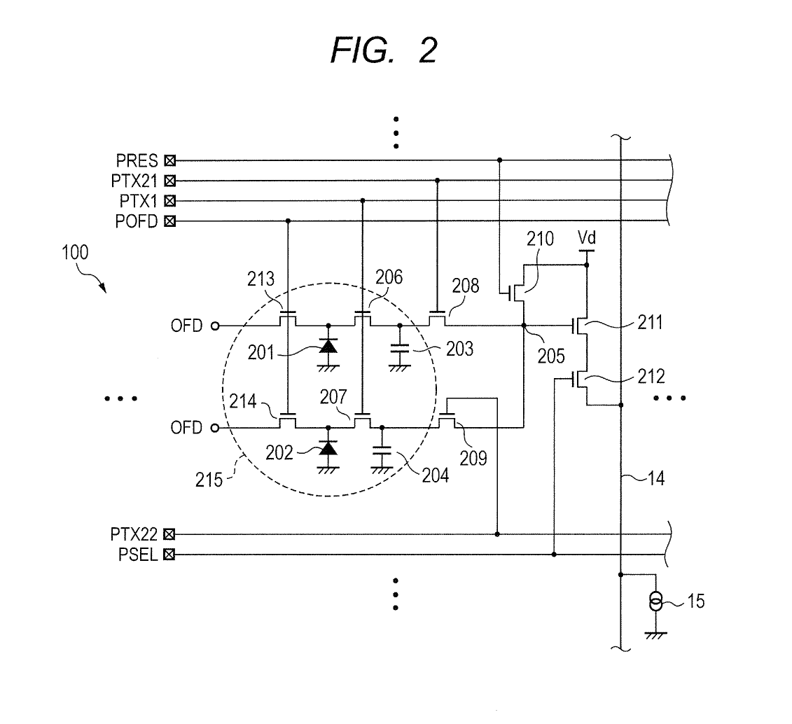

FIG. 2 is a circuit diagram of the pixel 100 according to the first embodiment. The pixel 100 includes photoelectric converters (PDs) 201 and 202, charge holding portions (MEMs) 203 and 204, and a floating diffusion (FD) 205. Each of the PDs 201 and 202 includes a photoelectric conversion element such as a photodiode configured to generate charges corresponding to the amount of incident light. The MEMs 203 and 204 are elements configured to temporarily hold the charges generated by the PDs 201 and 202, respectively.

The pixel 100 further includes first transfer transistors 206 and 207 configured to transfer the charges from the PDs 201 and 202 to the MEMs 203 and 204, respectively, and second transfer transistors 208 and 209 configured to transfer the charges from the MEMs 203 and 204 to the FD 205, respectively. The first transfer transistors 206 and 207 are controlled to be turned on or off based on a control signal PTX1. The second transfer transistor 208 is controlled to be turned on or off based on a control signal PTX21, and the second transfer transistor 209 is controlled to be turned on or off based on a control signal PTX22.

The pixel 100 further includes a reset transistor 210, an amplifier transistor 211, and a select transistor 212. A drain of the reset transistor 210 is supplied with a reset voltage, and a source of the reset transistor 210 is connected to the FD 205. When the reset transistor 210 is turned on, the charges transferred to the FD 205 are reset. The FD 205 is a gate node of the amplifier transistor 211. The amplifier transistor 211 amplifies and outputs a signal corresponding to the amount of charges transferred to the FD 205. A source of the amplifier transistor 211 is connected to a drain of the select transistor 212, and a source of the select transistor 212 is connected to the vertical signal line 14. When the select transistor 212 is turned on, a pixel row to be read is selected, and the signal from the amplifier transistor 211 is output to the vertical signal line 14. The reset transistor 210 is controlled to be turned on or off based on a control signal PRES, and the select transistor 212 is controlled to be turned on or off based on a control signal PSEL.

The pixel 100 further includes overflow drains (OFDs) and OFD control transistors 213 and 214. The OFD control transistor 213 is connected between the photoelectric converter 201 and the OFD, and the control transistor 214 is connected between the photoelectric converter 202 and the OFD. The OFD control transistors 213 and 214 are controlled to be turned on or off based on a control signal POFD. When the OFD control transistors 213 and 214 are turned on, the PDs 201 and 202 are reset, respectively.

The pixel 100 further includes a microlens 215 (light condensing portion) configured to guide incident light into the PDs 201 and 202. The PDs 201 and 202 share the single microlens 215.

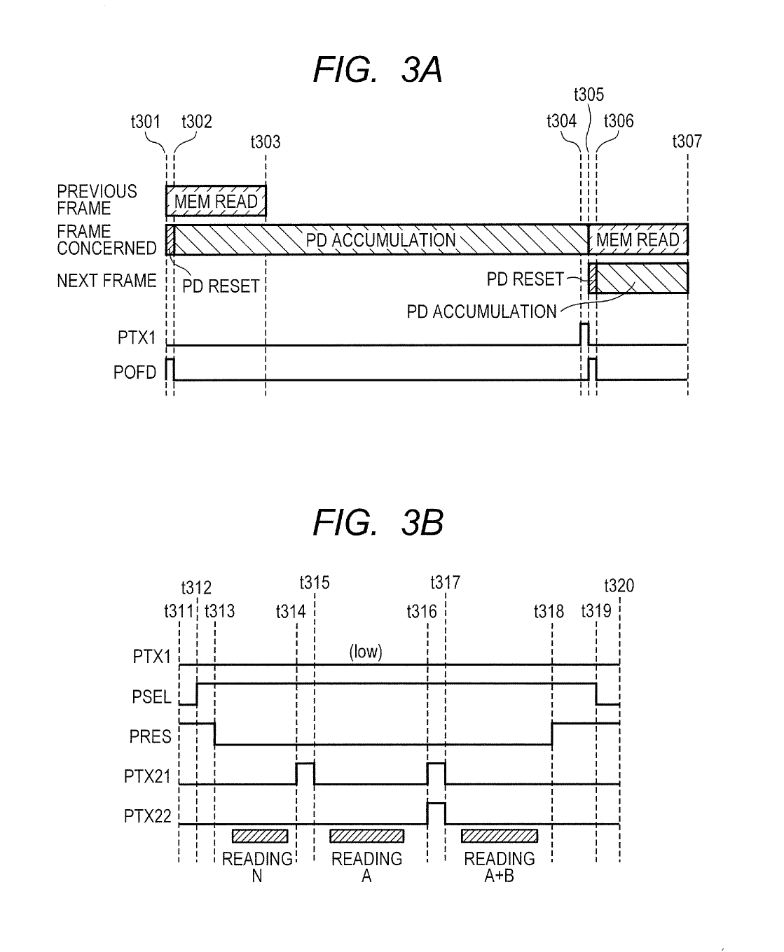

FIG. 3A and FIG. 3B are drive timing charts of the imaging apparatus according to the first embodiment. FIG. 3A is a timing chart for illustrating the operation in one frame period, and FIG. 3B is a timing chart for illustrating the operation in one horizontal period. One horizontal period is the period of reading pixel signals from one row. One frame period is the period of reading pixel signals from all the pixels.

Referring to FIG. 3A, the operation in one frame period is described. In the imaging apparatus 10 according to this embodiment, accumulation of charges in the PD for a certain frame and reading of a signal for another frame are performed simultaneously. Accordingly, there is a period during which pieces of processing for a plurality of frames are performed simultaneously at the same time. Thus, the following description may refer to not only a frame focused in the description herein (frame concerned) but also a frame preceding the focused frame (previous frame) and a frame subsequent to the focused frame (next frame). Note that, in the following description of the timing chart, each transistor is turned on (conductive) when each control signal is at High level, and each transistor is turned off (non-conductive) when each control signal is at Low level.

At a time t301, signals of the previous frame are held by the MEMs 203 and 204. In the period from the time t301 to a time t303, the signals of the previous frame are sequentially read (“MEM READ” in FIG. 3A).

In parallel to the reading of the signals of the previous frame, in the period from the time t301 to a time t305, the PDs 201 and 202 are reset and the charges are accumulated into the PDs 201 and 202 for the frame concerned (“PD RESET” and “PD ACCUMULATION” in FIG. 3A). In the period from the time t301 to a time t302, the control signal POFD becomes High level. Then, the OFD control transistors 213 and 214 are turned on, and the PDs 201 and 202 are reset. In this period, the control signal PTX1 is at Low level, and the first transfer transistors 206 and 207 are turned off.

At the time t302, the control signal POFD becomes Low level. The OFD control transistors 213 and 214 are turned off, and the signal charges start to be accumulated in the PDs 201 and 202 for all the pixels simultaneously.

In the period from a time t304 to the time t305, the control signal PTX1 becomes High level, and the first transfer transistors 206 and 207 are turned on. Then, the signal charges accumulated in the PDs 201 and 202 are transferred to the MEMs 203 and 204, respectively, for all the pixels simultaneously.

At the time t305, the control signal PTX1 becomes Low level, and the first transfer transistors 206 and 207 are turned off. Then, the accumulation of the signal charges for all the pixels is finished simultaneously. In this manner, the charge accumulation period for the PDs 201 and 202 is set to occur simultaneously for all the pixels, to thereby realize a global electronic shutter. Note that, in FIG. 3A, the first transfer transistors 206 and 207 are turned on only once in one frame period. However, in the period from the time t302 to the time t305, the first transfer transistors 206 and 207 may be turned on a plurality of times to transfer the charges of the PDs 201 and 202 to the MEMs 203 and 204 a plurality of times.

In the period from the time t305 to a time t306, the control signal POFD becomes High level, and the OFD control transistors 213 and 214 are turned on. Then, the charges of the PDs 201 and 202 are discharged to the OFDs, and the PDs 201 and 202 are reset. At the time t306, the control signal POFD becomes Low level, and the OFD control transistors 213 and 214 are turned off. After the time t306, signals for the next frame start to be accumulated into the PDs 201 and 202.

In the period from the time t305 to a time t307, the signal charges for the frame concerned accumulated in the MEMs 203 and 204 are sequentially read. The signal charges are read in accordance with the timing chart of FIG. 3B.

Next, referring to FIG. 3B, the operation in one horizontal period is described. At a time t311 of FIG. 3B, the control signals PTX1, PSEL, PTX21, and PTX22 are at Low level, and the control signal PRES is at High level. Accordingly, the first transfer transistors 206 and 207, the select transistor 212, and the second transfer transistors 208 and 209 are turned off, and the reset transistor 210 is turned on.

At a time t312, the control signal PSEL becomes High level, and the select transistors 212 of the pixels in the row to be read are turned on.

At a time t313, the control signal PRES becomes Low level, and the reset transistor 210 is turned off. Then, the reset of the FD 205 is canceled, and a signal corresponding to the reset level of the FD 205 is amplified by the amplifier transistor 211 to be output to the vertical signal line 14.

In the period from the time t313 to a time t314, the signal corresponding to the reset level of the FD 205 is obtained by a read circuit (column amplifier portion 16, column signal holding portion 17, etc.) (hereinafter referred to as “Reading N”).

In the period from the time t314 to a time t315, the control signal PTX21 becomes High level, and the second transfer transistor 208 is turned on. Then, the signal charges held by the MEM 203 are transferred to the FD 205. Then, a signal corresponding to the amount of charges held by the MEM 203 is amplified by the amplifier transistor 211 to be output to the vertical signal line 14.

In the period from the time t315 to a time t316, the signal corresponding to the amount of charges held by the MEM 203 is obtained by the read circuit (hereinafter referred to as “Reading A”).

In the period from the time t316 to a time t317, the control signals PTX21 and PTX22 become High level, and the signal charges held by the MEMs 203 and 204 are both transferred to the FD 205. Then, a signal corresponding to the sum of the amounts of charges held by the MEMs 203 and 204 is amplified by the amplifier transistor 211 to be output to the vertical signal line 14.

In the period from the time t317 to a time t318, the signal corresponding to the sum of the amounts of charges held by the MEMs 203 and 204 is obtained by the read circuit (hereinafter referred to as “Reading A+B”).

At the time t318, the control signal PRES becomes High level, and the reset transistor 210 is turned on. Then, the FD 205 is reset again.

At a time t319, the control signal PSEL becomes Low level, and the select transistor 212 is turned off. Then, the select of the pixel row is canceled.

In the period from the time t311 to a time t320, the reading of the signals from one row of the pixels 100 arranged in rows and columns in the pixel region 11 is completed. The reading rows are scanned to perform the above-mentioned operation sequentially for the respective rows, to thereby read the signals from all the pixels. When the time period required for the processing from the time t311 to the time t320 is represented by Th, the time period (Th×number of rows) corresponding to the reading time period for all the rows corresponds to the time period required from the time t301 to the time t303 or from the time t305 to the time t307 of FIG. 3A.

A difference between the signal obtained by Reading A and a signal obtained by Reading N is obtained, to thereby obtain a signal SA corresponding to the charges held by the MEM 203 in which noise such as reset noise has been removed. Similarly, a difference between the signal obtained by Reading A+B and the signal obtained by Reading A is obtained, to thereby obtain a signal SB corresponding to the charges held by the MEM 204. The use of the signal SA and the signal SB enables phase difference focus detection.

Based on a difference between the signal obtained by Reading A+B and the signal obtained by Reading N, a signal SAB corresponding to the sum of the charges held by the MEMs 203 and 204 is obtained. The signal SAB is used as a pixel signal for imaging. The signal SAB and the signals SA and SB are used for different purposes, and are therefore different in required accuracy. The accuracy of the signal SAB affects the image quality, and hence the signal SAB is required to have a high S/N ratio. On the other hand, the signals SA and SB are used only for focus detection, and hence may be allowed to be lower in accuracy than the signal SAB.

Note that, the timing charts illustrated in FIG. 3A and FIG. 3B assume moving image photography, but the configuration according to this embodiment is applicable also to still image photography. In this case, the frame interval can be lengthened, and hence the signal read period for the previous frame and the PD accumulation period for the frame concerned may not set to occur at the same time. For example, the PD accumulation for the frame concerned may start after the end of the signal reading for the previous frame.

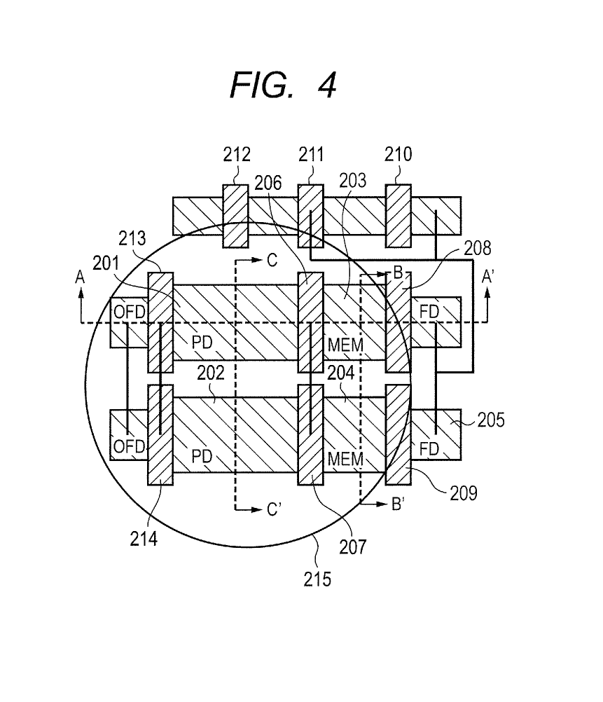

FIG. 4 is a top view of the pixel according to this embodiment. Portions corresponding to those in FIG. 2 are denoted by the same reference symbols as those in FIG. 2. In FIG. 4, the hatched regions denoted by reference symbols corresponding to the respective transistors such as the first transfer transistor 206 represent patterns of the gate electrodes, and the hatched regions of the PDs 201 and 202, the MEMs 203 and 204, and the FD 205 represent impurity diffusion regions. The connection relationships among the respective portions are the same as those in the circuit diagram illustrated in FIG. 2, and hence descriptions thereof are omitted.

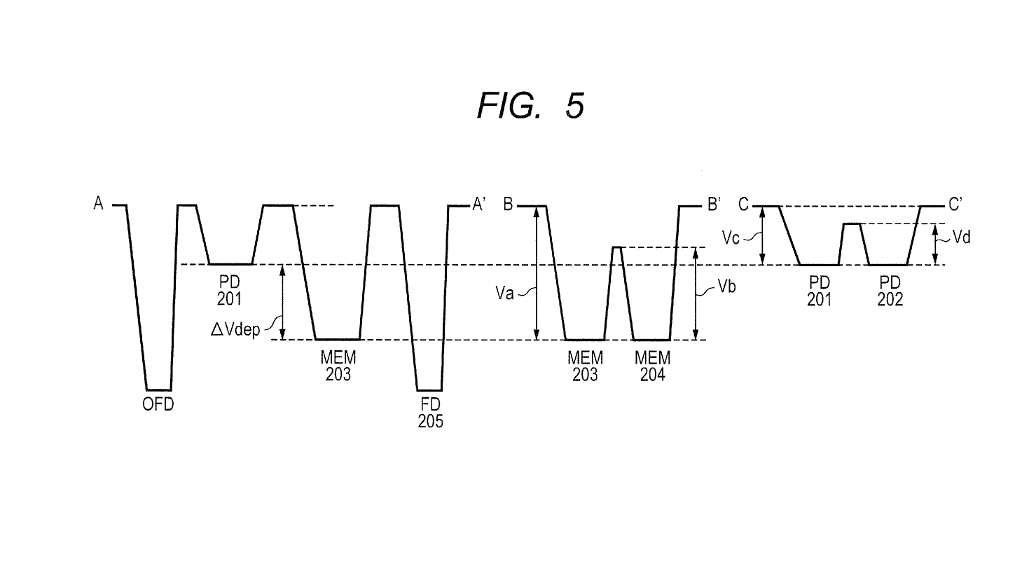

FIG. 5 is a potential diagram of the pixel according to this embodiment. Potentials indicated by A-A′, B-B′, and C-C′ of FIG. 5 correspond to the positions of A-A′, B-B′, and C-C′ of FIG. 4, respectively. The potential depth of the OFD is represented by V(OFD), the potential depth of the PD 201 is represented by V(PD 201), and the same applies to the other potential depths. Note that, the potential depth means a difference between a potential of a focused region and a potential of a region adjacent to the focused region. For example, the potential depth V(PD 201) of the PD 201 means a potential difference between a portion in which an impurity diffusion region of the PD 201 is formed and an outside region (such as an element isolation portion between pixels). In this case, the potential depths of the respective portions forming the pixel 100 have the following relationships.

V(OFD)≧V(FD205)

V(FD205)>V(MEM203)

V(MEM203)=V(MEM204)

V(MEM203)>V(PD201)

V(PD201)=V(PD202)

The above-mentioned relationships of the potential depths at the respective portions enable the charges to be completely transferred from the PDs 201 and 202 to the MEMs 203 and 204 and the charges to be completely transferred from the MEMs 203 to 204 to the FD 205. In this embodiment, a height Vb of a potential barrier between the MEM 203 and the MEM 204 is lower than a height Va of a potential barrier between the MEM 203 or the MEM 204 of the pixel concerned and the MEM of an adjacent pixel. The height of the potential barrier refers to potential energy required for signal charges in a region concerned to migrate to the outside of the region concerned.

Note that, the difference (V(MEM 203)−V(PD 201)) in potential depth between the PD 201 and the MEM 203 is a difference ΔVdep between a depletion voltage of the PD 201 and a depletion voltage of the MEM 203. The height Vb in this case may be higher or lower than the difference ΔVdep. In the configuration according to this embodiment illustrated in FIG. 5, Vb>ΔVdep is established. Further, the PD 201 is lower in potential than a peripheral region of the pixel, and hence ΔVdep and Va have the relationship of Va>ΔVdep.

A height Vd of a potential barrier between the PD 201 and the PD 202 and a height Vc of a potential barrier between the PD 201 or the PD 202 and the PD of an adjacent pixel have the relationship of Vd≦Vc. When Vd<Vc is established as illustrated in FIG. 5, even if one of the PDs 201 and 202 is saturated during the period of accumulating the charges in the PDs 201 and 202, the charges overflowing out of the one PD can be migrated to the other PD. Consequently, the saturation of the PD in the pixel concerned and the outflow of charges to an adjacent pixel can be reduced to improve the image quality.

In addition, in the period from the time t303 to the time t304, which is the signal accumulation period for the PDs 201 and 202, it is preferred to set the potential barrier between the PD 201 and the MEM 203 to be lower than the potential barrier between the PD 201 and the OFD. Consequently, the charges overflowing out of the PD 201 can be accumulated in the MEM 203 without being discarded to the OFD. In the period from the time t302 to the time t303, on the other hand, it is preferred to set the potential barrier between the PD 201 and the MEM 203 to be higher than the potential barrier between the PD 201 and the OFD. This is because this setting can reduce image quality degradation caused when the charges accumulated in the PD 201 in the frame concerned are mixed into the MEM 203 in which the signal for the previous frame is held.

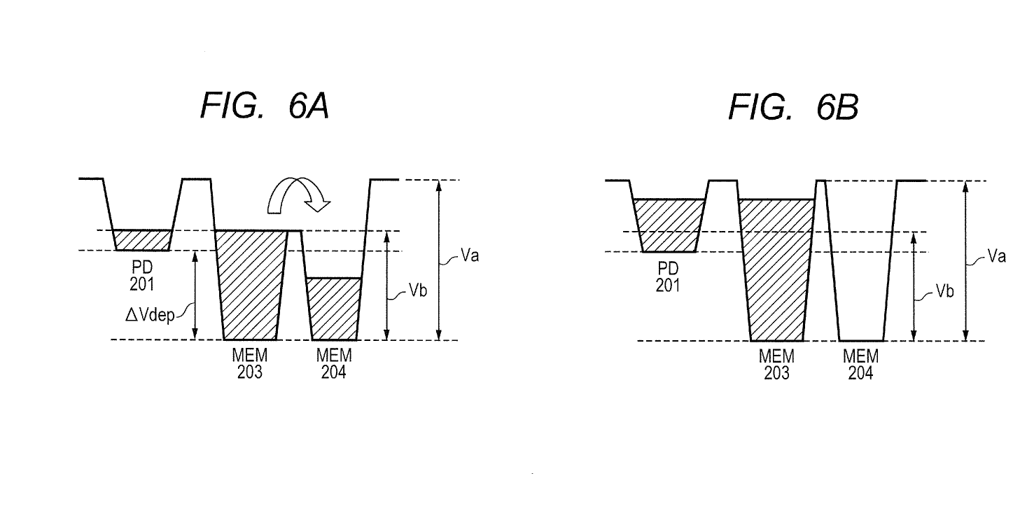

FIG. 6A is a potential diagram for illustrating the effects of this embodiment. FIG. 6B is a potential diagram according to a comparison example for comparison with this embodiment. The height of the potential barrier between the MEM 203 and the MEM 204 is Vb in FIG. 6A and Va in FIG. 6B. This is the difference between FIG. 6A and FIG. 6B. Now, a case is considered in which light enters only the PD 201 but does not enter the PD 202. In FIG. 6A and FIG. 6B, the potential relationships among the PD 201, the MEM 203, and the MEM 204 after the charges generated by the PD 201 are transferred to the MEM 203 are illustrated. Note that, the following description assumes that the charges generated by the PDs 201 and 202 and transferred to the MEMs 203 and 204 are electrons, but the signal charges may be holes. In this case, the conductivity type (p-type or n-type) of each impurity diffusion region to be described later is opposite to that described later. Further, the hatched regions in FIG. 6A and FIG. 6B schematically represent changes in potential at the respective portions due to the electrons accumulated in the respective portions.

When the number of electrons generated by the PD 201 is larger than the number of electrons that can be held by the MEM 203 without exceeding the height Vb of the potential barrier, in FIG. 6A, the electrons overflowing out of the MEM 203 flow into the MEM 204 beyond the height Vb of the potential barrier. In FIG. 6B, on the other hand, the electrons transferred to the MEM 203 do not migrate to the MEM 204 beyond the height Va of the potential barrier between the MEM 203 and the MEM 204, and hence the electrons generated by the PD 201 are distributed only to the PD 201 and the MEM 203. Accordingly, the number of electrons remaining in the PD 201 is smaller in the case of this embodiment illustrated in FIG. 6A than in the case of the comparative example illustrated in FIG. 6B. Consequently, according to this embodiment, the efficiency of transfer from the PD 201 to at least one of the MEM 203 or the MEM 204 is improved to improve the image quality.

Note that, as described above, when the number of electrons generated by the PD 201 exceeds the height Vb of the potential barrier, the electrons overflowing out of the MEM 203 are held by the MEM 204. In other words, the electrons originally required to be held by the MEM 203 migrate to the MEM 204, and hence the accuracy of the signals SA and SB for focus detection may deteriorate. In other words, the accuracy of the signals SA and SB for focus detection and the accuracy of the signal SAB for imaging may have a tradeoff relationship. However, because the signals SA and SB are the signals used for focus detection as described above, the accuracy of the signals SA and SB may be allowed to be lower than the accuracy of the signal SAB for imaging depending on the cases. In such a case, the accuracy of the signal SAB for imaging required to have a high S/N ratio can be enhanced without causing a problem of the degradation of the signals SA and SB for focus detection.

The migration of electrons to the MEM 204 illustrated in FIG. 6A may occur when the number of saturated electrons of the PD 201 is larger than the number of electrons that can be held by the MEM 203 without exceeding the height Vb of the potential barrier. However, even in the case where the number of saturated electrons of the PD 201 is smaller than the above-mentioned number of electrons, the situation of FIG. 6A may occur when the electrons are transferred from the PD 201 to the MEM 203 a plurality of times. Further, also when such an amount of light that generates a larger number of electrons than the number of saturated electrons of the PD 201 enters the PD 201, the situation of FIG. 6A may occur as long as the pixel has the potential structure in which the electrons overflowing out of the PD 201 beyond the number of saturated electrons of the PD 201 flow into the MEM 203 rather than the OFD. In any case, the same effects can be obtained through the setting of the height Vb of the potential barrier between the MEM 203 and the MEM 204 to be lower than the height Va of the potential barrier between the MEM 203 or the MEM 204 of the pixel concerned and the MEM of an adjacent pixel.

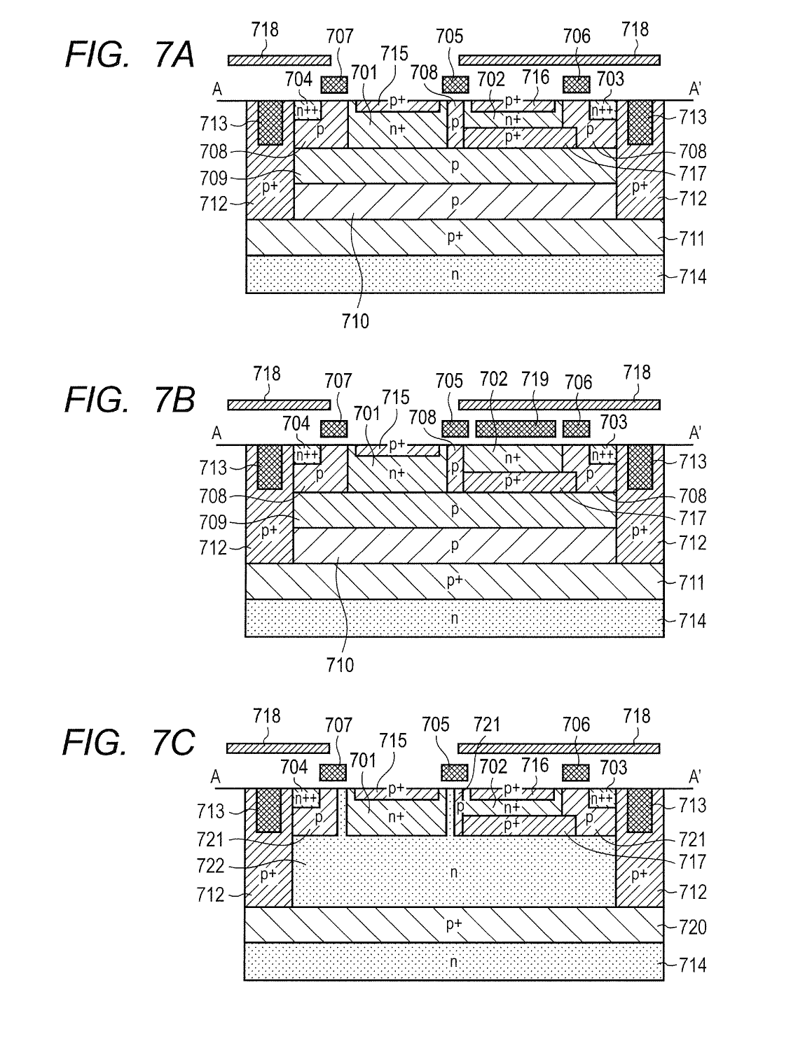

FIG. 7A, FIG. 7B, and FIG. 7C are exemplary illustrations of three kinds of the cross-sectional structure taken along the dotted line A-A′ of FIG. 4. The cross-sectional structure according to this embodiment may be any one of FIG. 7A, FIG. 7B, and FIG. 7C. The pixel 100 includes n-type semiconductor regions 701 to 704, 714, and 722 and p-type semiconductor regions 708 to 712, 715 to 717, 720, and 721, which are formed in a semiconductor substrate. The pixel 100 further includes gate electrodes 705 to 707 and 719, a field insulating film 713 configured to isolate the elements, and a light shielding film 718 configured to prevent incident light from entering regions other than the PDs. Note that, a gate insulating film (not illustrated) is formed between the gate electrodes and the semiconductor substrate.

In FIG. 7A, the n-type semiconductor regions 701, 702, 703, and 704 correspond to the PD 201, the MEM 203, the FD 205, and the OFD, respectively. The gate electrodes 705, 706, and 707 serve as gate electrodes of the first transfer transistor 206, the second transfer transistor 208, and the OFD control transistor 213, respectively. The n-type semiconductor regions 701 and 702 are formed below the p-type semiconductor regions 715 and 716 so that the PD 201 and the MEM 203 have a buried photodiode structure. This structure suppresses noise generated by defects at the interface between the semiconductor region and the insulating film. It is preferred that the n-type semiconductor region 701 be completely depleted when the charges of the PD 201 are transferred to the MEM 203 or when the charges of the PD 201 are discharged to the OFD. Further, it is preferred that the n-type semiconductor region 702 be completely depleted when the charges of the MEM 203 are transferred to the FD 205. The pixel is designed as described above so that the n-type semiconductor regions 701 and 702 are completely depleted when the electrons are transferred. Consequently, noise can be reduced. A complete depletion voltage of the n-type semiconductor region 701 is lower than a complete depletion voltage of the n-type semiconductor region 702. The difference between the complete depletion voltages corresponds to ΔVdep illustrated in FIG. 5.

In the p-type semiconductor regions 709 to 711, the p-type impurity concentration becomes higher as the depth in the substrate becomes larger. Accordingly, a potential gradient occurs in the depth direction of the substrate, and signal electrons generated at the deep part in the substrate are collected in the PD 201. The p-type semiconductor region 717 has an impurity concentration higher than that in the p-type semiconductor region 709, to thereby prevent the electrons generated at the deep part in the substrate from flowing into the MEM 203. Further, the electrostatic capacitance of the MEM 203 can be increased through an increase in electrostatic capacitance of the PN junction formed between the n-type semiconductor region 702 and the p-type semiconductor region 717. The p-type semiconductor region 712 has an impurity concentration higher than that in the p-type semiconductor region 710, to thereby have a function of electrically isolating the pixels.

FIG. 7B differs from FIG. 7A in that the p-type semiconductor region 716 is not formed in the surface of the MEM 203 and that the gate electrode 719 configured to control the potential of the n-type semiconductor region 702 is formed. When a negative voltage is applied to the gate electrode 719, the potential in the vicinity of the interface of the n-type semiconductor region 702 becomes higher to induce holes in the vicinity of the interface. Consequently, noise (dark current) generated by interface defects is reduced. Further, when a positive voltage is applied to the gate electrode 719, the potential in the vicinity of the interface of the n-type semiconductor region 702 becomes lower. Consequently, the efficiency of transfer of the charges from the PD 201 to the MEM 203 can also be improved.

In FIG. 7B, the gate electrode 705 of the first transfer transistor 206 is divided from the gate electrode 719, but the gate electrodes 705 and 719 may be electrically connected to each other so that the same voltage may be applied to the gate electrodes 705 and 719. In this case, when a voltage of High level is applied to the gate electrodes 705 and 719 to turn on the first transfer transistor 206, the charges are transferred from the PD 201 to the MEM 203 with high transfer efficiency. Further, when a voltage of Low level (negative voltage) is applied to the gate electrodes 705 and 719 to turn off the first transfer transistor 206, the charges are accumulated under the state in which the dark current at the interface is reduced.

FIG. 7C differs from FIG. 7A in that the p-type semiconductor regions 720 and 721 and the n-type semiconductor region 722 are formed in place of the p-type semiconductor regions 708 to 711. The n-type semiconductor region 722 is lower in impurity concentration than the n-type semiconductor region 701. The n-type semiconductor region 701 is connected to the n-type semiconductor region 722, and both of the n-type semiconductor regions 701 and 722 serve as a part of the PD 201. The pixel is designed so that the n-type semiconductor region 701 and the n-type semiconductor region 722 are completely depleted when the charges of the PD 201 are transferred to the MEM 203 or when the charges of the PD 201 are discharged to the OFD. Consequently, the noise can be reduced.

The p-type semiconductor region 720 serves as a potential barrier for preventing the electrons generated at a part deeper than the p-type semiconductor region 720 from flowing into the PD 201 by keeping the electrons generated at a part shallower than the p-type semiconductor region 720 in the PD 201. Accordingly, the depth of the PD 201 is determined by the depth of the p-type semiconductor region 720. The p-type semiconductor region 721 is a region for isolating the n-type semiconductor regions 702 to 704 from the n-type semiconductor region 722. The p-type semiconductor region 716 of FIG. 7C may be omitted, and the same gate electrode 719 for potential control as that of FIG. 7B may be added.

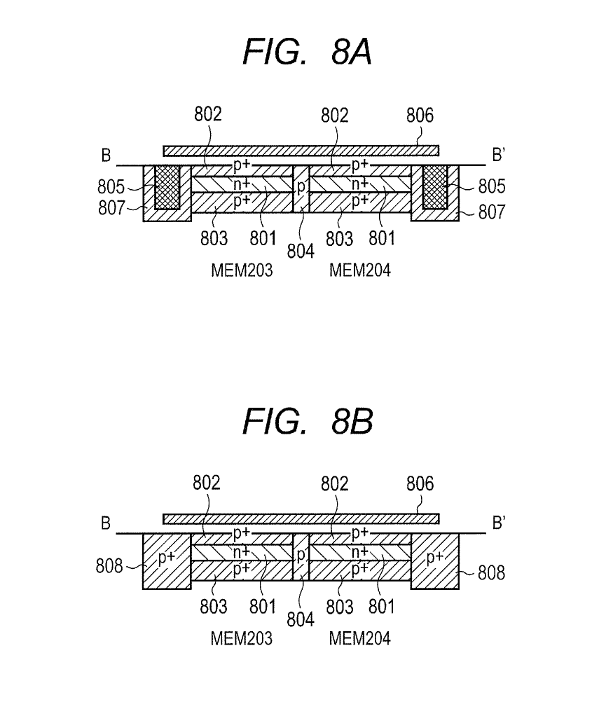

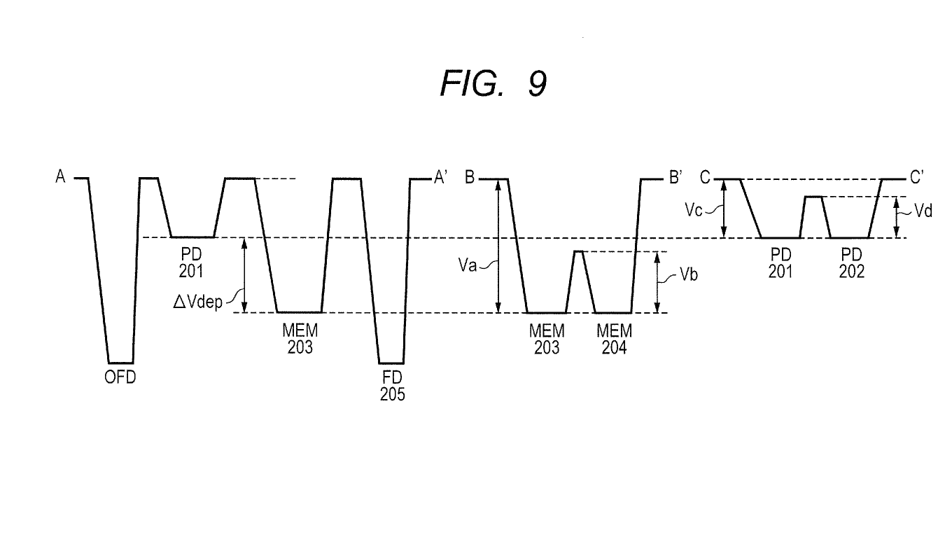

FIG. 8A and FIG. 8B are exemplary illustrations of two kinds of the cross-sectional structure in the vicinity of the interface taken along the dotted line B-B′ of FIG. 4. The cross-sectional structure according to this embodiment may be any one of FIG. 8A and FIG. 8B. The pixel 100 includes an n-type semiconductor region 801, p-type semiconductor regions 802 to 804 and 807, and a field insulating film 805, which are formed in the semiconductor substrate, and a gate electrode 806.

The n-type semiconductor region 801 corresponds to the n-type semiconductor region 702 of FIG. 7A. The p-type semiconductor region 802 corresponds to the p-type semiconductor region 716, and the p-type semiconductor region 803 corresponds to the p-type semiconductor region 717. The regions below the p-type semiconductor region 803 are the same as those in FIG. 7A, FIG. 7B, or FIG. 7C, and hence the illustration and descriptions thereof are omitted. The p-type semiconductor region 804 functions as an isolation portion configured to isolate the MEM 203 and the MEM 204 from each other.

In FIG. 8A, the field insulating film 805 functions as an isolation portion configured to isolate the MEM of the pixel concerned and the MEM of an adjacent pixel from each other or isolate the MEM and an element other than the MEM from each other. The p-type semiconductor region 807 is formed around the field insulating film 805 in order to reduce noise generated by defects at the interface between the field insulating film 805 and the semiconductor region. The field insulating film may be formed from an insulating material such as a silicon oxide.

In FIG. 8B, the p-type semiconductor region 808 is formed as an isolation portion in place of the field insulating film 805 and the p-type semiconductor region 807. The p-type semiconductor region 808 functions as an isolation portion configured to isolate the MEM of the pixel concerned and the MEM of an adjacent pixel from each other or isolate the MEM and an element other than the MEM from each other.

In FIG. 8A, the MEMs in the same pixel (MEM 203 and MEM 204) are isolated from each other by the p-type semiconductor region 804, but the MEM of the pixel concerned and the MEM of an adjacent pixel or the MEM and an element other than the MEM are isolated from each other by the field insulating film 805. In FIG. 8B, the impurity concentration of the p-type semiconductor region 804 configured to isolate the MEMs in the same pixel is lower than the impurity concentration of the p-type semiconductor region 808 configured to isolate the MEM of the pixel concerned and the MEM of an adjacent pixel or the MEM and an element other than the MEM from each other. Further, the distance between the MEMs in the same pixel is shorter than the distance between the MEM of the pixel concerned and the MEM of an adjacent pixel or the distance between the MEM and an element other than the MEM. Such a configuration realizes the structure in which the height Vb of the potential barrier between the MEM 203 and the MEM 204 is lower than the height Va of the potential barrier between the MEM 203 or the MEM 204 of the pixel concerned and the MEM of an adjacent pixel.

Note that, in FIG. 8A and FIG. 8B, the n-type semiconductor region 801 only needs to be isolated by the p-type semiconductor region 804. In other words, the element structure may be modified so that the p-type semiconductor regions 802 formed on the MEM 203 and the MEM 204 or the p-type semiconductor regions 803 formed under the MEM 203 and the MEM 204 may be connected to each other. Further, as illustrated in the cross-sectional structure of FIG. 7B, the p-type semiconductor region 802 may be omitted, and the gate electrode for potential control may be formed above the n-type semiconductor region 801 through intermediation of a gate insulating film.

### Second Embodiment

The difference between a second embodiment of the present invention and the first embodiment resides in that the height Vb of the potential barrier between the MEM 203 and the MEM 204 is lower than ΔVdep. In this embodiment, a circuit diagram of a pixel 100 is the same as that of FIG. 2, timing charts are the same as those of FIG. 3A and FIG. 3B, a top view of the pixel is the same as that of FIG. 4, a cross-sectional structure of the pixel taken along the dotted line A-A′ is the same as that of FIG. 7A, FIG. 7B, or FIG. 7C, and a cross-sectional structure of the pixel taken along the dotted line B-B′ is the same as that of FIG. 8A or FIG. 8B.

FIG. 9 is a potential diagram of the pixel according to this embodiment. The potential diagram of FIG. 9 differs from the potential diagram of FIG. 5 only in the height Vb of the potential barrier between the MEM 203 and the MEM 204. In this embodiment, the height Vb of the potential barrier between the MEM 203 and the MEM 204 is lower than the difference ΔVdep between the depletion voltage of the PD 201 and the depletion voltage of the MEM 203. Further, the height Va of the potential barrier between the MEM 203 or the MEM 204 of the pixel concerned and the MEM of an adjacent pixel is higher than ΔVdep. In other words, Va, Vb, and ΔVdep in this embodiment satisfy the relationship of Vb<ΔVdep<Va.

In the first embodiment, when the amount of charges generated by the PD 201 is larger than the number of electrons that can be held by the MEM 203 without exceeding the depletion voltage difference ΔVdep, the electrons of the PD 201 are not completely transferred to the MEM 203, but a part of the charges remain in the PD 201. The charges remaining in the PD 201 are not read as a signal, and hence the linearity of the output with respect to the amount of incident light is not maintained, which may be a cause of image quality degradation. According to this embodiment, the amount of charges remaining in the PD 201 can be reduced to further improve the image quality.

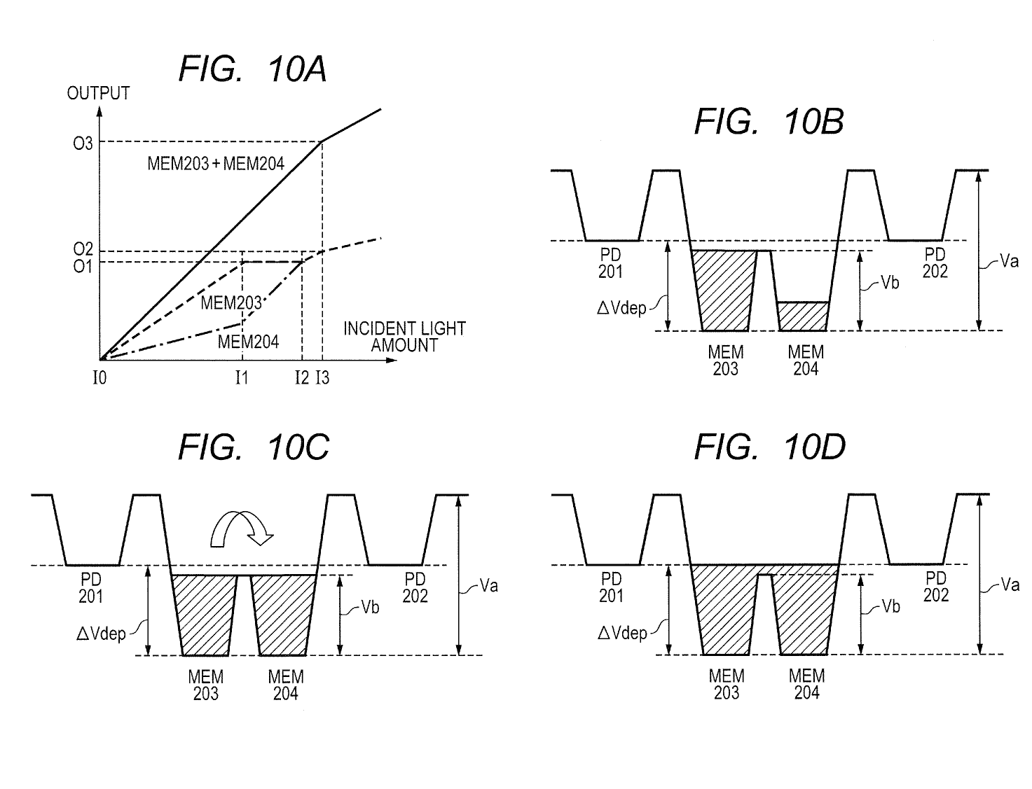

FIG. 10A is a graph for illustrating the effects of this embodiment, and FIG. 10B, FIG. 10C, and FIG. 10D are potential diagrams for illustrating the effects of this embodiment. Referring to FIG. 10A to FIG. 10D, the mechanism of improving the image quality by the configuration in this embodiment is described.

FIG. 10A is a graph for illustrating a relationship between the amount of incident light and the output in the imaging apparatus 10 according to this embodiment. The graph of FIG. 10A assumes a situation in which, when light enters the pixel 100, a larger amount of the light enters the PD 201 than the PD 202. It is assumed that, even when the amount of incident light is changed, the ratio between the amount of light entering the PD 201 and the amount of light entering the PD 202 is constant. In FIG. 10A, an output corresponding to the amount of charges of the MEM 203 is indicated by the broken line, an output corresponding to the amount of charges of the MEM 204 is indicated by the dashed line, and an output corresponding to the sum of the amounts of charges of the MEM 203 and the MEM 204 is indicated by the solid line.

When the amount of light entering the pixel 100 falls within the range of from I0 to I1, the charges held by the MEM 203 do not exceed the height Vb of the potential barrier between the MEM 203 and the MEM 204. When the amount of light is I1, the maximum amount of charges that can be held without exceeding the height Vb of the potential barrier between the MEM 203 and the MEM 204 are generated by the PD 201. FIG. 10B is a potential diagram after the amount of light I1 enters the PD 201 and the PD 202 and the generated electrons are transferred to the MEM 203 and the MEM 204. When the amount of incident light falls within the range of from I0 to I1, the charges accumulated in the PD 201 and the PD 202 are completely transferred to the MEM 203 and the MEM 204, and hence the charges accumulated in the PD 201 and the PD 202 are all read. Thus, as understood from the graph in the range of from I0 to I1 in FIG. 10A, the relationship between the amount of incident light and the output is linear.

When the amount of incident light falls within the range of from I1 to I2, some of the electrons generated by the PD 201 exceeding the height Vb of the potential barrier overflow to the MEM 204. When the amount of light is I2, the charges are accumulated in the MEM 203 and the MEM 204 until the potentials of the MEM 203 and the MEM 204 reach the potentials of the height Vb of the potential barrier. FIG. 10C is a potential diagram when the amount of light is I2. When the amount of incident light falls within the range of from I1 to I2, the number of electrons of the MEM 203 is constant. Thus, when the amount of light increases within the range of from I1 to I2, electrons corresponding to the increased amount of light are all accumulated in the MEM 204. Also in this case, the electrons generated by the PD 201 and the PD 202 are completely transferred to the MEM 203 and the MEM 204, and hence the linearity between the amount of incident light and the output of “MEM 203+MEM 204” is maintained.

When the amount of incident light falls within the range of from I2 to I3, the charges generated by the PD 201 and the PD 202 are held by both of the MEM 203 and the MEM 204. In this case, the amounts of charges transferred to the MEM 203 and the MEM 204 are equal to each other. FIG. 10D is a potential diagram when the amount of light is I3. Also in this region, the linearity between the amount of incident light and the output of “MEM 203+MEM 204” is maintained.

When the amount of incident light exceeds I3, an increase in potential due to the transferred charges exceeds ΔVdep, and hence the charges of the PD 201 or the PD 202 cannot be completely transferred but remain in the PD 201 or the PD 202 after the charges are transferred to the MEM 203 and the MEM 204. Thus, a part of the generated charges are not read, and hence the linearity between the amount of incident light and the output of “MEM 203+MEM 204” is not maintained as illustrated in FIG. 10A, resulting in a decrease in inclination of the graph.

According to this embodiment, the height Vb of the potential barrier between the MEM 203 and the MEM 204 is set to be lower than the difference ΔVdep between the depletion voltage of the PD 201 and the depletion voltage of the MEM 203. Consequently, the linearity between the amount of incident light and the output of “MEM 203+MEM 204” is maintained in the range where the amount of incident light is equal to or smaller than I3, that is, in the range where the amount of incident light is equal to or smaller than such an amount of incident light that the charges corresponding to ΔVdep are held by both of the MEM 203 and the MEM 204.

### Third Embodiment

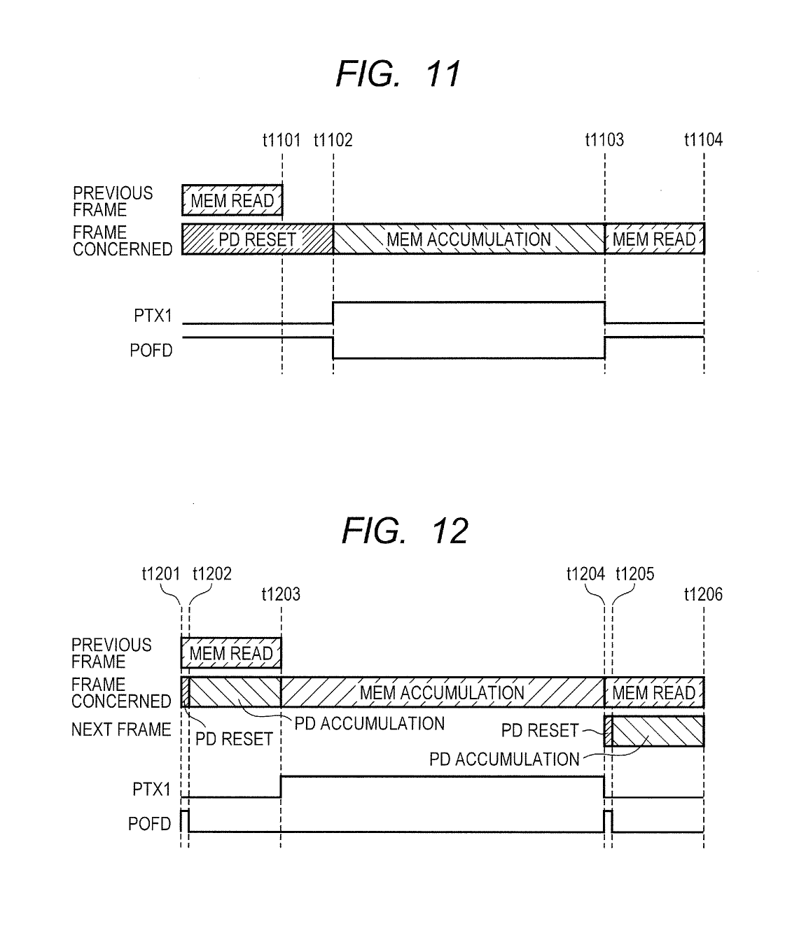

The difference between a third embodiment of the present invention and the first and second embodiments resides in that the signal charges are accumulated in the MEMs 203 and 204 rather in the PDs 201 and 202. FIG. 11 is a timing chart for illustrating the operation in one frame period according to this embodiment. A top view, a potential diagram, and a cross-sectional structure of a pixel 100 according to this embodiment are the same as those in the first and second embodiments. Specifically, the top view in this embodiment is the same as that of FIG. 4, the potential diagram in this embodiment is the same as that of FIG. 5 or FIG. 9, the cross-sectional structure of the pixel taken along the dotted line A-A′ in this embodiment is the same as that of FIG. 7A, FIG. 7B, or FIG. 7C, and the cross-sectional structure of the pixel taken along the dotted line B-B′ in this embodiment is the same as that of FIG. 8A or FIG. 8B. Further, a timing chart in one horizontal period is the same as that of FIG. 3B. Overlapping descriptions thereof are omitted.

At a time t1101, reading of signals for the previous frame is finished. At this time, the control signal PTX1 is at Low level and the control signal POFD is at High level. In other words, the first transfer transistors 206 and 207 are off, the OFD control transistors 213 and 214 are on, and the PDs 201 and 202 are reset.

At a time t1102, the control signal POFD becomes Low level, and the OFD control transistors 213 and 214 are turned off. At the same time, the control signal PTX1 becomes High level, and the first transfer transistors 206 and 207 are turned on. Then, the signal charges start to be accumulated for all the pixels simultaneously. In the period from the time t1102 to a time t1103, because the first transfer transistors 206 and 207 are on, the signal charges generated by the PDs 201 and 202 are immediately transferred and accumulated in the MEMs 203 and 204.

At the time t1103, the control signal PTX1 becomes Low level. Then, the first transfer transistors 206 and 207 are turned off, and the accumulation of the signals is finished for all the pixels simultaneously. At the same time, the control signal POFD becomes High level, and the OFD control transistors 213 and 214 are turned on. Then, the PDs 201 and 202 are reset again. After that, in the period from the time t1103 to a time t1104, the signal charges held by the MEMs 203 and 204 are sequentially read.

The imaging apparatus 10 including the pixel 100 illustrated in FIG. 2 has an electronic shutter function. Accordingly, the imaging apparatus 10 according to each of the above-mentioned embodiments includes a larger number of transfer transistors than in an imaging apparatus not having the electronic shutter function, and tends to have a large area. Thus, in a situation where there is a constraint on the area of the circuits of the imaging apparatus 10 due to requirements for miniaturizing the pixels, increasing in the number of pixels, and the like, there may also be a constraint on the numbers of saturated electrons of the PDs 201 and 202 and the MEMs 203 and 204. According to the driving method in this embodiment, the charges are not accumulated in the PDs 201 and 202, and hence the number of saturated electrons of the PDs 201 and 202 can be designed to be small. The area obtained by this effect can be allocated to the MEMs 203 and 204 so that the number of saturated electrons of the MEMs 203 and 204 can be designed to be large, and hence the dynamic range can be enlarged.

According to this embodiment, when the signal charges are generated by the PDs 201 and 202, the signal charges are immediately transferred and accumulated in the MEMs 203 and 204. Accordingly, it is preferred to set the height Vb of the potential barrier between the MEM 203 and the MEM 204, which are included in the same pixel and adjacent to each other, to be higher than the height Vd of the potential barrier between the PD 201 and the PD 202, which are included in the same pixel and adjacent to each other.

According to the configuration in this embodiment, the dynamic range can be enlarged in addition to the effects of the first and second embodiments.

### Fourth Embodiment

The difference between a fourth embodiment of the present invention and the first to third embodiments resides in that the pixel operates so that the signal charges generated in the signal read period for the previous frame are accumulated in the PDs 201 and 202 and the signal charges generated in periods other than the signal read period are accumulated in the MEMs 203 and 204. A top view, a potential diagram, and cross-sectional structures of the pixel 100 in this embodiment are the same as those in the first to third embodiments. Specifically, the top view in this embodiment is the same as that of FIG. 4, the potential diagram in this embodiment is the same as that of FIG. 5 or FIG. 9, the cross-sectional structure of the pixel taken along the dotted line A-A′ in this embodiment is the same as that of FIG. 7A, FIG. 7B, or FIG. 7C, and the cross-sectional structure of the pixel taken along the dotted line B-B′ in this embodiment is the same as that of FIG. 8A or FIG. 8B. Further, a timing chart in one horizontal period is the same as that of FIG. 3B. Overlapping descriptions thereof are omitted.

FIG. 12 is a timing chart in one frame period according to this embodiment. The difference from FIG. 3A resides in that, in the period from a time t1203 to a time t1204, the signal charges are accumulated in the MEMs 203 and 204 rather in the PDs 201 and 202. Driving in the period from a time t1201 to the time t1203 is the same as the driving in the period from the time t301 to the time t303 of FIG. 3A, and hence a description thereof is omitted.

At the time t1203, the control signal PTX1 becomes High level, and the first transfer transistors 206 and 207 are turned on. Then, the charges accumulated in the PDs 201 and 202 in the period from the time t1202 to the time t1203 are transferred to the MEMs 203 and 204.

In the period from the time t1203 to the time t1204, the control signal PTX1 is maintained at High level, and hence the first transfer transistors 206 and 207 are maintained to be on. Accordingly, the charges generated by the PDs 201 and 202 are immediately transferred and accumulated in the MEMs 203 and 204. At the time t1204, the control signal PTX1 becomes Low level, and the first transfer transistors 206 and 207 are turned off. Then, all the pixels finish the signal accumulation simultaneously. Driving in the subsequent period from the time t1204 to a time t1206 is the same as the driving in the period from the time t305 to the time t307 of FIG. 3A.

According to the driving method in the third embodiment, the electrons generated by the PDs 201 and 202 are not accumulated in the period from the time t1103 to the time t1104, which is the signal read period. According to the driving method in this embodiment, on the other hand, the signal charges generated in the signal read period for the previous frame can also be accumulated. In addition, the period of accumulating the electrons in the PDs 201 and 202 is shorter than that in the example illustrated in FIG. 3A, and hence the number of electrons required to be accumulated in the PDs 201 and 202 is smaller than that in the first and second embodiments. Consequently, similarly to the third embodiment, the number of saturated electrons of the PDs 201 and 202 can be designed to be small and the number of saturated electrons of the MEMs 203 and 204 can be designed to be large accordingly, and hence the dynamic range can be enlarged.

Note that, in FIG. 12, the control signal PTX1 is illustrated as being always at High level in the period from the time t1203 to the time t1204. However, the effect of enlarging the dynamic range can be obtained even when the electrons are transferred to the MEMs 203 and 204 before the PDs 201 and 202 are saturated, and hence the control signal PTX1 may be set to High level intermittently in the period from the time t1203 to the time t1204. In this case, the control signal PTX1 is not always at High level, and hence the accumulation of dark current generated by defects at a silicon/silicon oxide film interface formed under the gates of the first transfer transistors 206 and 207 can be reduced to further improve the image quality.

Also in this embodiment, it is preferred to set the height Vb of the potential barrier between the MEM 203 and the MEM 204, which are included in the same pixel and adjacent to each other, to be higher than the height Vd of the potential barrier between the plurality of PDs 201 and 202, which are included in the same pixel and adjacent to each other.

According to the configuration in this embodiment, the dynamic range can be enlarged in addition to the effects of the first and second embodiments.

### Fifth Embodiment

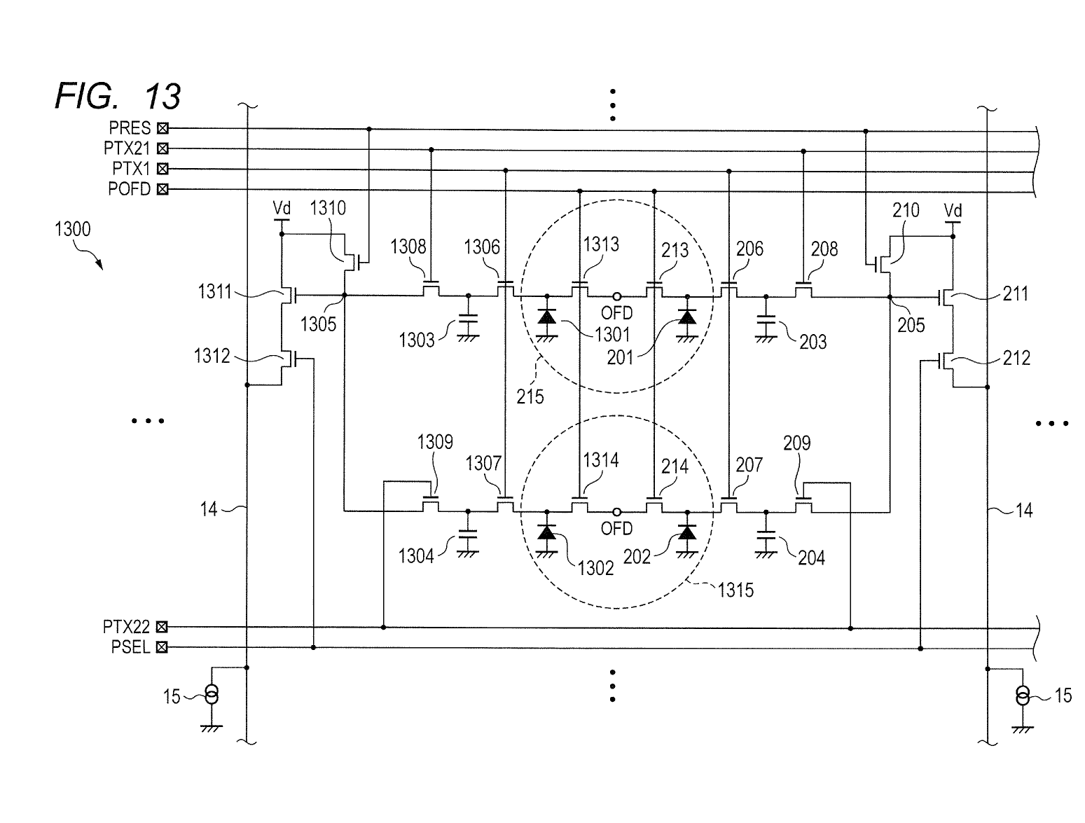

The difference between a fifth embodiment of the present invention and the first to fourth embodiments resides in that signals of a plurality of PDs in the same pixel are read with use of a plurality of different FDs. FIG. 13 is a circuit diagram of two pixels according to this embodiment. Portions having the same functions as those in FIG. 2 are denoted by the same reference symbols. Further, reference numerals 1301 to 1315 denote the portions corresponding to reference numerals 201 to 215, respectively, and the respective portions have the same functions. The microlens 215 is formed above the PD 201 and the PD 1301, and the PDs 201 and 1301 serve as the PDs of one pixel. The microlens 1315 is formed above the PDs 202 and 1302, and the PD 202 and the PD 1302 serve as the PDs of another pixel.

Drive timings in one frame period according to this embodiment may be the same as those in any one of the first, third, and fourth embodiments. In other words, the timing chart of any one of FIG. 3A, FIG. 11, and FIG. 12 is applicable also to this embodiment.

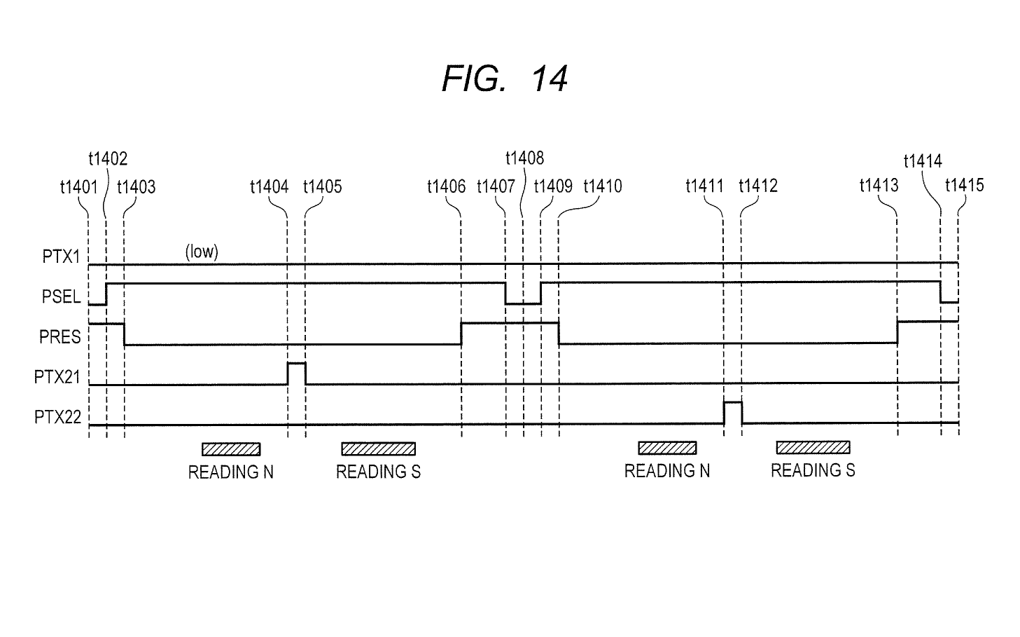

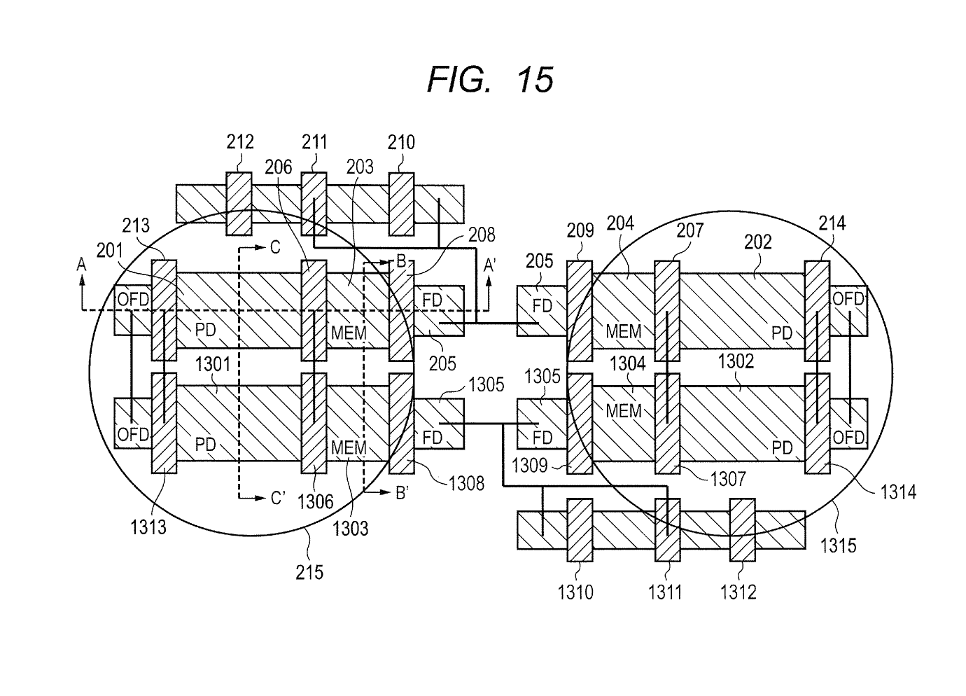

FIG. 14 is a timing chart in two horizontal periods according to this embodiment. Operations of the control signals PTX1, PSEL, and PRES in the period from a time t1401 to a time t1408 and driving in the period from the time t1408 to a time t1415 are the same as the driving in the period from the time t311 to the time t320 of FIG. 3B, and hence descriptions thereof are omitted.

Operations of the control signals PTX21 and PTX22 of FIG. 14 differ from those of the control signals PTX21 and PTX22 of FIG. 3B. In the period from the time t1404 to the time t1405, the control signal PTX21 becomes High level, and the second transfer transistors 208 and 1308 are turned on. Then, the charges held by the MEMs 203 and 1303 are transferred to the FDs 205 and 1305, respectively. After that, signals amplified by the amplifier transistors 211 and 1311 are output to the vertical signal lines 14 in the period from the time t1405 to the time t1406. After that, signals corresponding to the amounts of the charges held by the MEMs 203 and 1303 are obtained by the read circuit (hereinafter referred to as “Reading S”).

In the period from the time t1411 to the time t1412, the control signal PTX22 becomes High level, and the second transfer transistors 209 and 1309 are turned on. Then, the charges held by the MEMs 204 and 1304 are transferred to the FDs 205 and 1305, respectively. After that, signals amplified by the amplifier transistors 211 and 1311 are output to the vertical signal lines 14 in the period from the time t1412 to the time t1413. In other words, the signals of the PDs in the same pixel (PD 201 and PD 1301, or PD 202 and PD 1302) are read with use of different FDs (FD 205 and FD 1305). After that, Reading S of the signals corresponding to the amounts of the charges held by the MEMs 204 and 1304 is performed.

Note that, in FIG. 13, the PDs in different pixels (for example, PD 201 and PD 202) share the FD used for signal reading (for example, FD 205). However, the FD is not necessarily required to be shared between different pixels. An FD, an amplifier transistor, a reset transistor, and a select transistor may be arranged individually for each PD.

FIG. 15 is a top view of two pixels according to this embodiment. Portions corresponding to those in FIG. 13 are denoted by the same reference symbols as those in FIG. 13. The cross-sectional structure taken along the dotted line A-A′ of FIG. 15 may be the same as that of FIG. 7A, FIG. 7B, or FIG. 7C, and the cross-sectional structure of the pixel taken along the dotted line B-B′ of FIG. 15 may be the same as that of FIG. 8A or FIG. 8B. Further, the potentials in each cross-section may be the same as those of FIG. 5 or FIG. 9. The same effects as those in the first or second embodiment can be obtained also in this embodiment through the setting of the potentials.

### Sixth Embodiment

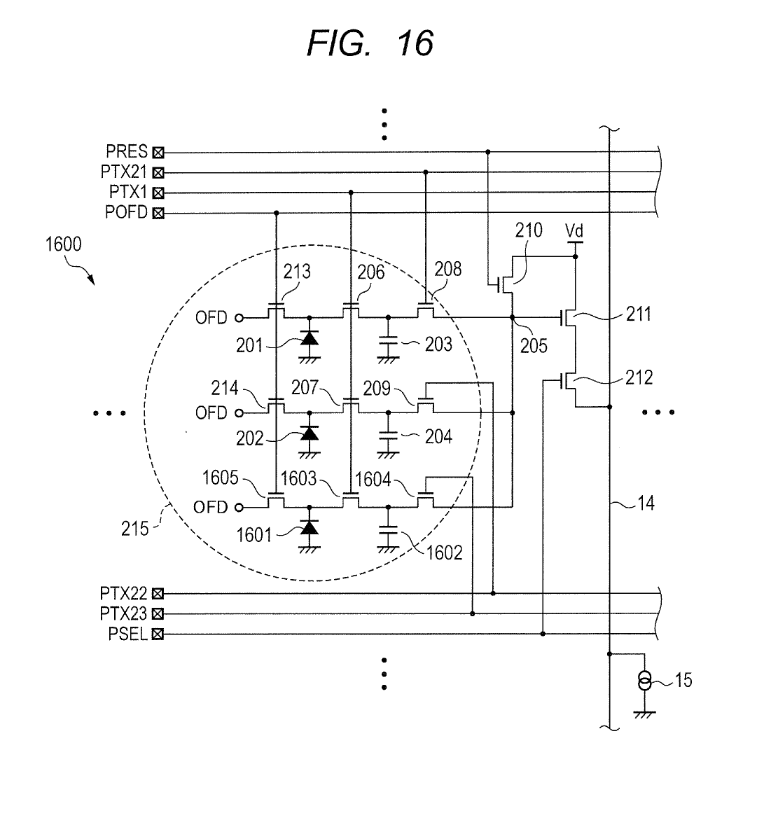

The difference between a sixth embodiment of the present invention and the first to fifth embodiments resides in that each pixel includes at least three PDs and at least three MEMs corresponding to the at least three PDs. FIG. 16 is a circuit diagram of the pixel according to this embodiment. The same portions as those in FIG. 2 are denoted by the same reference symbols. As compared to FIG. 2, a pixel 1600 according to this embodiment further includes a PD 1601, a MEM 1602, a first transfer transistor 1603, a second transfer transistor 1604, and an OFD control transistor 1605.

Drive timings in one frame period according to this embodiment may be the same as those in any one of the first, third, and fourth embodiments. In other words, the timing chart of any one of FIG. 3A, FIG. 11, and FIG. 12 is applicable also to this embodiment.

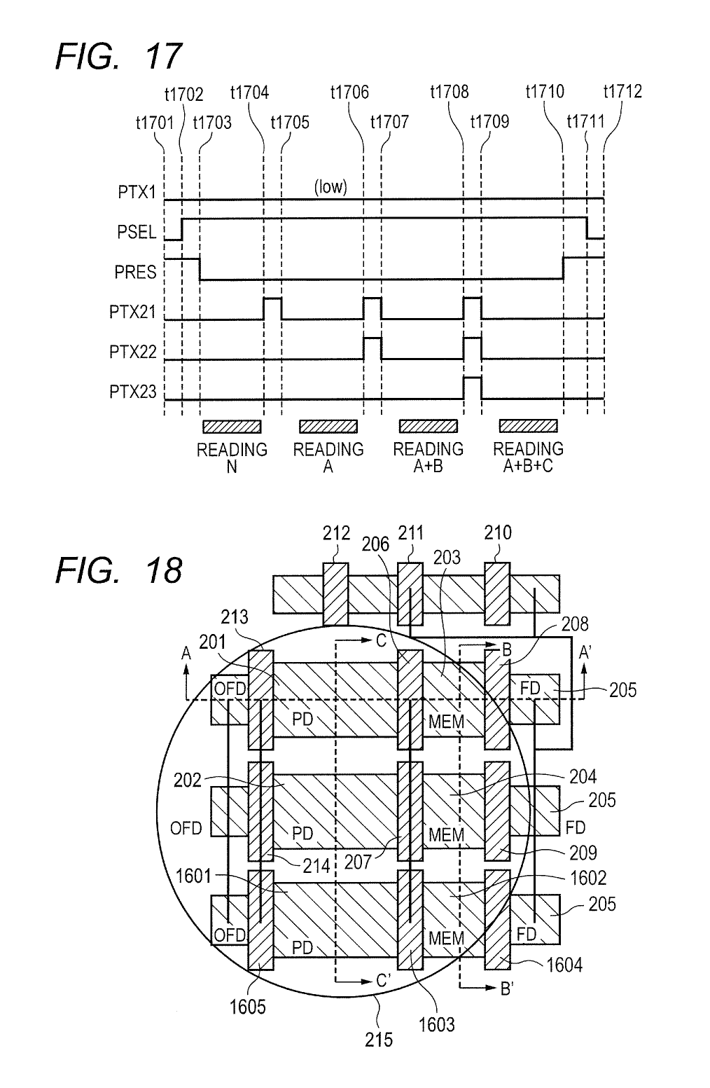

FIG. 17 is a timing chart of reading of pixel signals from one row according to this embodiment. Driving in the period from a time t1701 to a time t1708 is the same as the driving in the period from the time t311 to the time t318 of FIG. 3B, and hence a description thereof is omitted. In the period from the time t1708 to a time t1709, the control signals PTX21, PTX22, and PTX23 become High level, and the second transfer transistors 208, 209, and 1604 are turned on. Then, the signal charges of the MEMs 203, 204, and 1602 are all transferred to the FD 205. In the period from the time t1709 to a time t1710, a signal obtained by adding the signal charges generated by the PDs 201, 202, and 1601 is output (Reading A+B+C). Driving in the period from the time t1710 to a time t1712 is the same as the driving in the period from the time t318 to the time t320 of FIG. 3B.

FIG. 18 is a top view of the pixel according to this embodiment. FIG. 18 is the same as FIG. 4 except that the PD 1601, the MEM 1602, the first transfer transistor 1603, the second transfer transistor 1604, and the OFD control transistor 1605 are added, and hence a detailed description thereof is omitted.

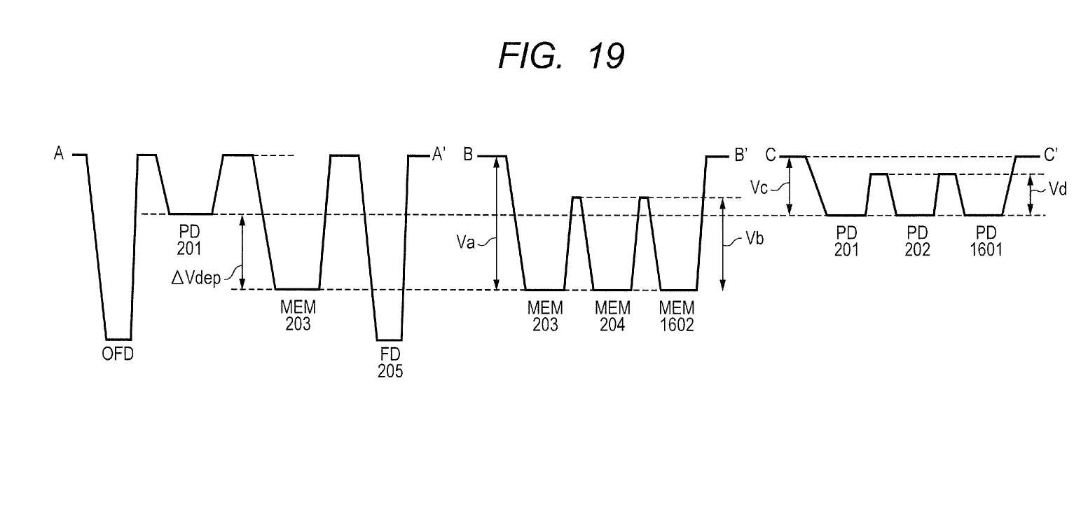

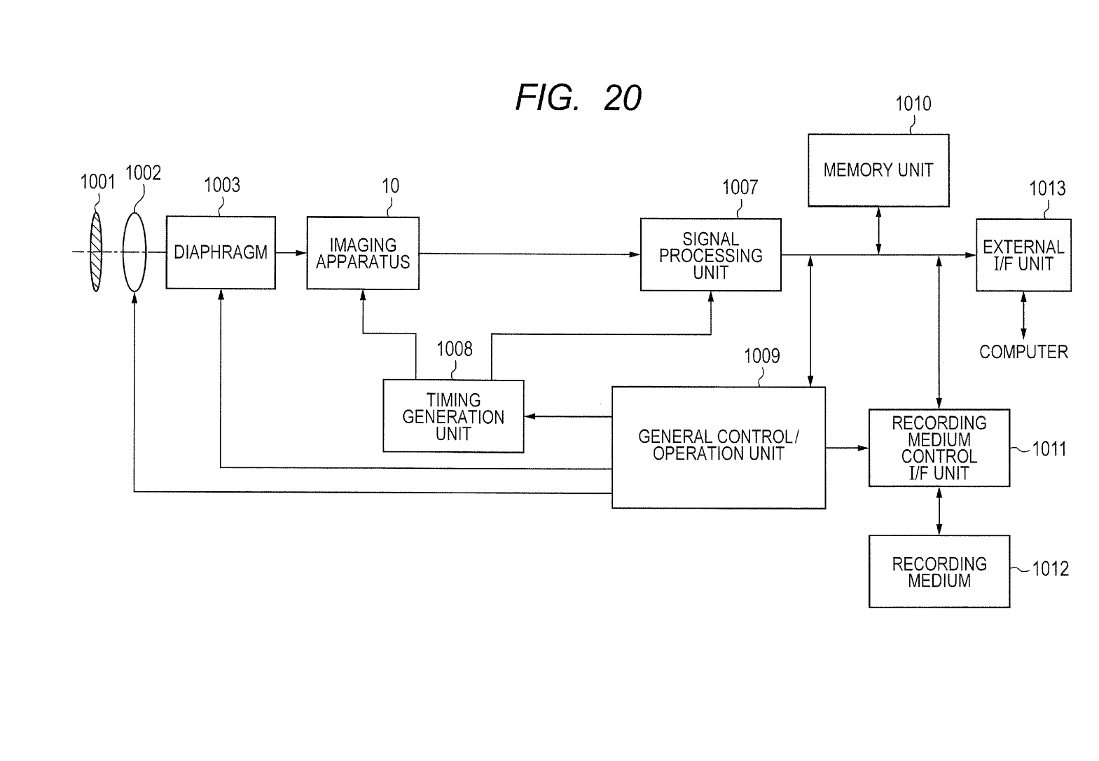

In FIG. 19, a potential relationship of the pixel among the regions taken along the dotted lines A-A′, B-B′, and C-C′ of FIG. 18 is illustrated. In this embodiment, similarly to the first embodiment, the height Vb of the potential barrier among the MEMs 203, 204, and 1602 included in the same pixel is lower than the height Va of the potential barrier between the MEMs of adjacent pixels. Consequently, the same effects as those in the first embodiment can be obtained also in this embodiment. Further, the height Vb of the potential barrier may be set to be lower than the difference ΔVdep between the depletion voltage of the PD 201 and the depletion voltage of the MEM 203. Consequently, the same effects as those in the second embodiment can be obtained also in this embodiment.

In FIG. 18, the three MEMs are illustrated as being all arranged in proximity to one another. However, the numbers of the PDs and the MEMs may be four or more, and the same effects can be obtained. Further, when the number of the MEMs is four or more, all the MEMs may not be arranged in proximity to one another but may be arranged to be divided into some groups. In such a case, the same effects can be obtained through the decrease in potential barrier between a plurality of the MEMs arranged in proximity to each other.

### Seventh Embodiment

As a seventh embodiment of the present invention, an imaging system using the imaging apparatus according to the first to sixth embodiments is described. Examples of the imaging system include a digital still camera, a digital camcorder, a camera head, a copying machine, a facsimile machine, a mobile phone, an on-board camera, and an observation satellite. FIG. 20 is a block diagram of a digital still camera, for illustrating an example of a configuration of the imaging system according to this embodiment.

In FIG. 20, the imaging system includes a barrier 1001 configured to protect a lens, a lens 1002 configured to form an optical image of an object onto the imaging apparatus 10, and a diaphragm 1003 configured to adjust the amount of light passing through the lens 1002. In this case, the imaging apparatus 10 is the imaging apparatus according to the above-mentioned first to sixth embodiments, and converts the optical image formed by the lens 1002 into image data.

The imaging system further includes a signal processing unit 1007, a timing generation unit 1008, a general control/operation unit 1009, a memory unit 1010, a recording medium control interface (I/F) unit 1011, a recording medium 1012, and an external I/F unit 1013. The signal processing unit 1007 performs various kinds of processing, such as noise correction and data compression, on imaging data output from the imaging apparatus 10. The timing generation unit 1008 outputs various kinds of timing signals to the imaging apparatus 10 and the signal processing unit 1007. The general control/operation unit 1009 controls the entire digital still camera. The memory unit 1010 temporarily stores the image data. The recording medium control I/F unit 1011 is an I/F unit configured to record or read data to or from the recording medium 1012. The recording medium 1012 is a removable recording medium such as a semiconductor memory or a recording medium built in the imaging system, which is configured to record or read the imaging data. Then, the external I/F unit 1013 is an interface unit configured to communicate to and from an external computer and the like.

The timing signals may be input from the outside of the imaging system. The imaging system only needs to include at least the imaging apparatus 10 and the signal processing unit (signal processing device) 1007 configured to process an imaging signal output from the imaging apparatus 10.

Further, the signal processing unit 1007 may be configured to process a signal based on the charges generated by the first PD 201 and a signal based on the charges generated by the second PD 202, to thereby obtain distance information from the imaging apparatus 10 to an object.

The imaging system according to this embodiment includes the imaging apparatus according to the first to sixth embodiments as the imaging apparatus 10. Consequently, according to this embodiment, the imaging system with improved image quality can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. For example, any configurations described in the different embodiments may be combined in various ways.

This application claims the benefit of Japanese Patent Application No. 2014-206281, filed Oct. 7, 2014, which is hereby incorporated by reference herein in its entirety.

What is claimed is:

1. An imaging apparatus, comprising a pixel region in which a plurality of pixels are arranged, the plurality of pixels each comprising:
a plurality of photoelectric converters configured to generate charges corresponding to an amount of incident light;
a plurality of charge holding portions arranged correspondingly to the plurality of photoelectric converters and configured to hold charges generated by the plurality of photoelectric converters respectively; and
a light condensing portion arranged so as to be shared by the plurality of photoelectric converters and configured to guide the incident light to the plurality of photoelectric converters,
wherein a height Vb of a first potential barrier between two of the plurality of charge holding portions included in a same pixel is lower than a height Va of a second potential barrier between two of the plurality of charge holding portions included in different pixels.

2. The imaging apparatus according to claim 1, wherein the height Vb of the first potential barrier is lower than a difference ΔVdep between a depletion voltage of one of the plurality of photoelectric converters and a depletion voltage of corresponding one of the plurality of charge holding portions.

3. The imaging apparatus according to claim 2, wherein the difference ΔVdep is lower than the height Va of the second potential barrier.

4. The imaging apparatus according to claim 1, wherein a height Vd of a third potential barrier between two of the plurality of photoelectric converters included in a same pixel is lower than a height Vc of a fourth potential barrier between two of the plurality of photoelectric converters included in different pixels.

5. The imaging apparatus according to claim 1, wherein the height Vb of the first potential barrier is higher than a height Vd of a third potential barrier between two of the plurality of photoelectric converters included in the same pixel.

6. The imaging apparatus according to claim 1, further comprising:
a first isolation portion formed between adjacent ones of the plurality of charge holding portions included in a same pixel, the first isolation portion being formed of a semiconductor region having a conductivity type that is different from a conductivity type of a semiconductor region forming the plurality of charge holding portions; and
a second isolation portion formed between adjacent ones of the plurality of charge holding portions included in different pixels, the second isolation portion being formed of an insulating material.

7. The imaging apparatus according to claim 1, further comprising:
a first isolation portion formed between adjacent ones of the plurality of charge holding portions included in a same pixel, the first isolation portion being formed of a first semiconductor region having a conductivity type that is different from a conductivity type of a semiconductor region forming the plurality of charge holding portions; and
a second isolation portion formed between adjacent ones of the plurality of charge holding portions included in different pixels, the second isolation portion being formed of a second semiconductor region having the conductivity type that is different from the conductivity type of the semiconductor region forming the plurality of charge holding portions,
wherein an impurity concentration of the first semiconductor region is lower than an impurity concentration of the second semiconductor region.

8. An imaging apparatus, comprising:
a pixel region in which a plurality of pixels are arranged, the plurality of pixels each comprising:
a plurality of photoelectric converters configured to generate charges corresponding to an amount of incident light;
a plurality of charge holding portions arranged correspondingly to the plurality of photoelectric converters and configured to hold charges generated by the plurality of photoelectric converters respectively; and
a light condensing portion arranged so as to be shared by the plurality of photoelectric converters and configured to guide the incident light to the plurality of photoelectric converters;
a first isolation portion formed between adjacent ones of the plurality of charge holding portions included in a same pixel, the first isolation portion being formed of a semiconductor region having a conductivity type that is different from a conductivity type of a semiconductor region forming the plurality of charge holding portions; and
a second isolation portion formed between adjacent ones of the plurality of charge holding portions included in different pixels, the second isolation portion being formed of an insulating material.

9. An imaging apparatus, comprising:
a pixel region in which a plurality of pixels are arranged, the plurality of pixels each comprising:
a plurality of photoelectric converters configured to generate charges corresponding to an amount of incident light;
a plurality of charge holding portions arranged correspondingly to the plurality of photoelectric converters and configured to hold charges generated by the plurality of photoelectric converters respectively; and
a light condensing portion arranged so as to be shared by the plurality of photoelectric converters and configured to guide the incident light to the plurality of photoelectric converters;
a first isolation portion formed between adjacent ones of the plurality of charge holding portions included in a same pixel, the first isolation portion being formed of a first semiconductor region having a conductivity type that is different from a conductivity type of a semiconductor region forming the plurality of charge holding portions; and
a second isolation portion formed between adjacent ones of the plurality of charge holding portions included in different pixels, the second isolation portion being formed of a second semiconductor region having the conductivity type that is different from the conductivity type of the semiconductor region forming the plurality of charge holding portions,
wherein an impurity concentration of the first semiconductor region is lower than an impurity concentration of the second semiconductor region.

10. An imaging apparatus, comprising a pixel region in which a plurality of pixels are arranged, the plurality of pixels each comprising:
a plurality of photoelectric converters configured to generate charges corresponding to an amount of incident light;
a plurality of charge holding portions arranged correspondingly to the plurality of photoelectric converters and configured to hold charges generated by the plurality of photoelectric converters respectively; and
a light condensing portion arranged so as to be shared by the plurality of photoelectric converters and configured to guide the incident light to the plurality of photoelectric converters,
wherein a height Vb of a first potential barrier between two of the plurality of charge holding portions included in a same pixel is lower than a difference ΔVdep between a depletion voltage of one of the plurality of photoelectric converters and a depletion voltage of corresponding one of the plurality of charge holding portions.

11. The imaging apparatus according to claim 10, wherein a height Vd of a third potential barrier between two of the plurality of photoelectric converters included in a same pixel is lower than a height Vc of a fourth potential barrier between two of the plurality of photoelectric converters included in different pixels.

12. The imaging apparatus according to claim 10, wherein the height Vb of the first potential barrier is higher than a height Vd of a third potential barrier between two of the plurality of photoelectric converters included in the same pixel.

13. An imaging system, comprising:
an imaging apparatus, comprising a pixel region in which a plurality of pixels are arranged, the plurality of pixels each comprising:
a plurality of photoelectric converters configured to generate charges corresponding to an amount of incident light;
a plurality of charge holding portions arranged correspondingly to the plurality of photoelectric converters and configured to hold charges generated by the plurality of photoelectric converters respectively; and
a light condensing portion arranged so as to be shared by the plurality of photoelectric converters and configured to guide the incident light to the plurality of photoelectric converters,
wherein a height Vb of a first potential barrier between two of the plurality of charge holding portions included in a same pixel is lower than a height Va of a second potential barrier between two of the plurality of charge holding portions included in different pixels; and
a signal processing device configured to process a signal output from the imaging apparatus.

14. The imaging system according to claim 13, wherein the signal processing device is configured to process a signal that is based on charges generated by a first photoelectric converter of the plurality of photoelectric converters and a signal that is based on charges generated by a second photoelectric converter of the plurality of photoelectric converters, which are output from the imaging apparatus, to thereby obtain distance information from the imaging apparatus to an object.
